(19) United States
(12) Patent Application Publication
(10) Pub. No.: US 2026/0319372 A1
(43) Pub. Date: Oct. 15, 2026

(54) Systems, Methods, And Devices For Illumination In Lithography

(71) Applicant: EUV Tech, Inc., Martinez, CA (US)

(72) Inventor: Patrick Naulleau, Pleasant Hill, CA (US)

(21) Appl. No.: 19/174,592

(22) Filed: Apr. 9, 2025

(51) Int. Cl. G03F 7/20; G03F 7/00

(52) U.S. Cl. CPC G03F 7/2008; G03F 7/70233; G03F 7/70408

(57) ABSTRACT

Systems, methods, and devices disclosed herein illuminate lithography targets in various operational environments. Systems include a light source configured to generate a first optical output and an optical device configured to receive the first optical output. The optical device includes a collector optic configured to receive the first optical output from the light source, and further configured to generate a second optical output based, at least in part, on the first optical output, the second optical output comprising a collected beam of light produced by the light source, and a collimator optic configured to receive the second optical output from the collector optic, and further configured to generate a third optical output that includes substantially collimated light.

### FIELD OF TECHNOLOGY

This patent application relates generally to lithography, and more specifically to extreme ultraviolet (EUV) illumination for lithography.

### BACKGROUND

Lithography techniques may use one or more patterning techniques to apply a pattern to a lithography target. For example, photolithography may use light to induce changes in the lithography target that may subsequently be used to etch a pattern in the lithography target. The pattern itself may be represented in a photomask which may be used in combination with a resist that coats the lithography target itself. The photomask and resist may be exposed using a light source that is configured for such photolithography operations. Conventional techniques for illuminating such photomasks and resists remain limited because they are not able to efficiently provide high-resolution illumination of such photomasks and resists.

### SUMMARY

In some embodiments, techniques described herein relate to a system for illumination for interference-based lithography. In some embodiments, the techniques described herein relate to a system including: a light source configured to generate a first optical output; and an optical device configured to receive the first optical output, the optical device including: a collector optic configured to receive the first optical output from the light source, and further configured to generate a second optical output based, at least in part, on the first optical output, the second optical output including a collected beam of light produced by the light source; and a collimator optic configured to receive the second optical output from the collector optic, and further configured to generate a third optical output that includes substantially collimated light.

In some embodiments, the techniques described herein relate to a system further including a reflector optic positioned between the collector optic and the collimator optic. In some embodiments, the techniques described herein relate to a system further including a reflector optic positioned between the light source and the collector optic. In some embodiments, the techniques described herein relate to a system, wherein the collimator optic includes a plurality of aspherical mirrors configured to receive a noncollimated optical input, and further configured to generate a substantially collimated optical output based on the received noncollimated optical input.

In some embodiments, the techniques described herein relate to a system, wherein an orientation of the second optical output of the collector optic is substantially orthogonal to a lithography target. In some embodiments, the techniques described herein relate to a system, wherein the collimator optic includes at least one of a reflection zone plate and a transmission zone plate. In some embodiments, the techniques described herein relate to a system further including: an optical grating configured to receive the third optical output, and further configured to generate a fourth optical output provided to a lithography target. In some embodiments, the techniques described herein relate to a system, wherein the optical grating includes a multiple-grating interferometer. In some embodiments, the techniques described herein relate to a system, wherein the light source is an extreme ultraviolet (EUV) light source configured to generate EUV light.

In some embodiments, the techniques described herein relate to a device including: a collector optic configured to receive a first optical output from a light source, and further configured to generate a second optical output based, at least in part, on the first optical output, the second optical output including a collected beam of light produced by the light source; and a collimator optic configured to receive the second optical output from the collector optic, and further configured to generate a third optical output that includes substantially collimated light, the third optical output being capable of being provided to a lithography target.

In some embodiments, the techniques described herein relate to a device further including a reflector optic positioned between the collector optic and the collimator optic. In some embodiments, the techniques described herein relate to a device further including a reflector optic positioned between the light source and the collector optic. In some embodiments, the techniques described herein relate to a device, wherein the collimator includes a plurality of aspherical mirrors configured to receive a noncollimated optical input, and further configured to generate a substantially collimated optical output based on the received noncollimated optical input.

In some embodiments, the techniques described herein relate to a device, wherein an orientation of the second optical output of the collector optic is substantially orthogonal to the lithography target. In some embodiments, the techniques described herein relate to a device further including: an optical grating configured to receive the third optical output, and further configured to generate a fourth optical output provided to the lithography target, wherein the optical grating includes a multiple-grating interferometer.

In some embodiments, the techniques described herein relate to a method including: receiving a first optical output from a light source; generating, using collector optic, a second optical output based on the first optical output, the second optical output including a collected beam of light produced by the light source; providing the second optical output to collimator optic; and generating, using the collimator optic, a third optical output including collimated light, the third optical output being capable of being provided to a lithography target.

In some embodiments, the techniques described herein relate to a method, wherein a reflector optic is positioned between the collector optic and the collimator optic and provides the second optical output from the collector optic to the collimator optic. In some embodiments, the techniques described herein relate to a method, wherein a reflector optic is positioned between the light source and the collector optic and provides the first optical output from the light source to the collector optic. In some embodiments, the techniques described herein relate to a method, wherein the collimator includes a plurality of aspherical mirrors that receive a noncollimated optical input, and generate a collimated optical output based on the received noncollimated optical input.

In some embodiments, the techniques described herein relate to a method, wherein an optical grating receives the third optical output, and further generates a fourth optical output provided to the lithography target, wherein the optical grating includes a multiple-grating interferometer. These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, methods, and devices for illumination for lithography. These drawings in no way limit any changes in form and detail that may be made by one skilled in the art without departing from the spirit and scope of the disclosed implementations.

FIG. 1 illustrates an example of a system for lithography illumination, configured in accordance with some embodiments.

FIG. 2 illustrates an example of a device for lithography illumination, configured in accordance with some embodiments.

FIG. 3 illustrates another example of a device for lithography illumination, configured in accordance with some embodiments.

FIG. 4 illustrates an additional example of a device for lithography illumination, configured in accordance with some embodiments.

FIG. 5 illustrates another example of a device for lithography illumination, configured in accordance with some embodiments.

FIG. 6 illustrates an example of a method for lithography illumination, performed in accordance with some embodiments.

FIG. 7 illustrates another example of a method for lithography illumination, performed in accordance with some embodiments.

### DETAILED DESCRIPTION

In various embodiments, resists may be used during lithography operations applied to lithography targets, such as silicon wafers. Moreover, illumination and imaging techniques may be used for testing such resists used in lithography operations. For example, a light source may be used to generate light that illuminates the lithography target covered by a resist layer, and thus provides illumination during testing and imaging operations of the lithography target. Accordingly, lithography operations disclosed herein may include one or more testing operations used to test an integrity of the resist layer, and ensure the resist layer may be used for subsequent lithography operations.

Conventional techniques for generating light used in interference-based EUV lithography remain limited because they often rely on large and expensive coherent light sources for such applications. More specifically, collimated EUV light sources may be used to generate light for such lithography operations. However, such coherent light sources are expensive and often not feasibly implemented with lithography systems. For example, such coherent-source EUV interference lithography tools must typically be implemented using large facility scale light sources, such as synchrotron facilities. Alternatively, compact (table-top) coherent light sources such as high harmonic generation (HHG) sources might be used. However, such table-top coherent sources are limited in their ability to generate a photon flux sufficient for EUV resist layer testing with sufficient area and speed.

Embodiments disclosed herein enable the usage of incoherent light sources with interference-based EUV lithography operations and testing of resist layers. As will be discussed in greater detail below, an initial EUV light source may be an incoherent noncollimated light source. One or more configurations of collector optics and collimator optics may be configured to receive such incoherent light, and generate a partially coherent, nominally collimated output that has sufficient photon flux for EUV lithography operations, such as testing of resist layers. In this way, a relatively low-cost and less resource intensive EUV light source may be used, thus improving the ability to implement such resist layer testing.

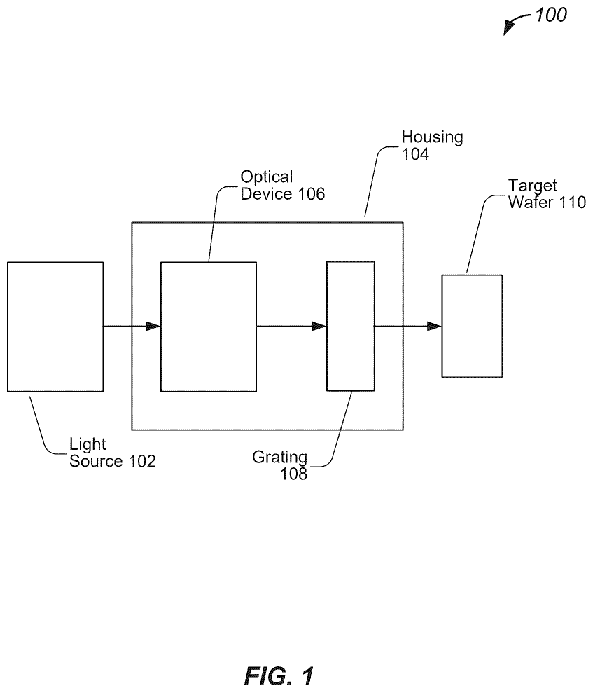

FIG. 1 illustrates an example of a system for interference lithography illumination, configured in accordance with some embodiments. As similarly discussed above, embodiments disclosed herein enable the highly efficient collection of light from an incoherent light source while maintaining divergence parameters suitable for interference lithography applications. Accordingly, a system, such as system 100, may be configured to provide such light collection and collimation to enable efficient and relatively low-cost generation of partially-coherent light for interference lithography.

In various embodiments, system 100 includes light source 102 which is configured to generate light used for lithography operations described herein. In various embodiments, light source 102 is configured to generate EUV light. Moreover, light source 102 may generate such EUV light in an incoherent manner. In this way, an output of light source 102 is not coherent and is not collimated. In various embodiments, light source 102 may be configured to generate EUV light based on the generation of a laser produced plasma. In some embodiments, light source 102 is configured to generate EUV light based on the generation of discharge produced plasma. It will be appreciated that any suitable technique for generating EUV light is contemplated and disclosed herein. Moreover, while various embodiments describe the use of EUV light, any suitable wavelengths of light may be used for lithography applications. For example, light source 102 may generate x-ray wavelengths, such as soft x-ray wavelengths.

System 100 additionally includes optical device 106 which is configured to receive an optical output from light source 102. As will be discussed in greater detail below, optical device 106 may include one or more optical elements configured to collect light from light source 102, and generate a collected beam of light based on the collected light. Accordingly, optical device 106 may include a collector mirror or other collector optical element, and may also include a flat mirror that may be used to guide the collected beam to one or more downstream components. As will also be discussed in greater detail below, optical device 106 may also include collimator optical elements that are configured to collimate the collected beam. Accordingly, the collimator optical elements may generate an output that is nominally collimated, and such collimated output may be provided to one or more downstream components.

In various embodiments, optical device 106 may be included in a housing, such as housing 104, which is configured to provide mechanical and structural support for optical device 106 and components of optical device 106. In some embodiments, housing 104 may also include grating 108 discussed in greater detail below. However, while FIG. 1 illustrates grating 108 as included in housing 104, in various embodiments, grating 108 is implemented separately and outside of housing 104 as its own stand-alone component of system 100.

System 100 further includes grating 108 which is configured to include an optical grating used for interference lithography purposes. In various embodiments, the optical grating includes multiple optical gratings that may provide an amount of diffraction and/or convergence, and thus may be configured as a multi-grating interferometer. For example, grating 108 may be a dual grating where diffraction from a first grating causes the collimated beam received from optical device 106 to split into multiple beams upon propagation. A second grating may be placed downstream at a distance configured to allow the diffracted orders to be completely separated spatially. In various embodiments, the second grating has half the pitch of the first grating. The second grating may also include opaque regions, also referred to herein as stops, that are configured to block the zero order (undiffracted light) from the first grating, and one or more higher orders from the first diffraction grating. In various embodiments, grating 108 may be included in an illumination module that is used for interference-based lithography operations. The second grating is configured to cause the diffracted beams to recombine at a distance equal to the distance between the first grating and the second grating. A resist-coated wafer, such as target wafer 110 may be at this point of recombination to record the interference pattern. In some embodiments, the longitudinal length over which interference occurs is determined based on the coherence area of the illuminating beam.

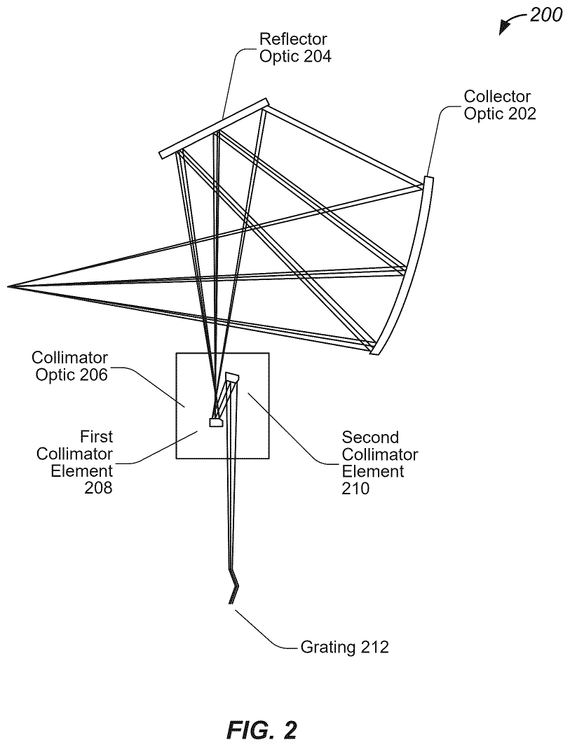

FIG. 2 illustrates an example of a device for lithography illumination, configured in accordance with some embodiments. As similarly discussed above, embodiments disclosed herein enable the highly efficient collection of light from an incoherent light source while maintaining divergence parameters suitable for interference lithography applications. Accordingly, a device, such as device 200, may include optical elements configured to provide a large angle of light collection and collimation to enable such efficient generation of coherent light for interference lithography.

As similarly discussed above, device 200 may be configured to receive light from a light source which may be an EUV light source. The light source may be an incoherent light source, and thus provide incoherent light to device 200. In various embodiments, device 200 includes collector optic 202 which is configured to receive the incoherent light from the light source, and is further configured to generate a collected beam of light that converges the collected beam and concentrates the light subsequently used for collimation. In some embodiments, collector optic 202 includes a collector mirror that is configured to collect an angular range of at least 5 degrees of the light generated by the light source. The collector mirror may be configured to re-concentrate the collected light with a magnification value of approximately 1. It will be appreciated that such magnification value may be determined and configured based on illumination parameters of the light source as well as illumination parameters of a grating. In this way, collector optic 202 is configured based on illumination parameters and constraints of the lithography process for a downstream target, which may be a target wafer.

In some embodiments, collector optic 202 is an aspherical collector mirror that is covered with an EUV reflective coating that is matched to a target operating wavelength used for lithography. More specifically, such wavelength may be about 13.5 nm. As discussed above, collector optic 202 may be configured to operate with other wavelength ranges as well. For example, collector optic 202 may include a reflective coating that matches a target operating wavelength of about 6.7 nm. Accordingly, a collector mirror included in collector optic 202 may be coated with a multi-layer coating that is configured to reflect the target operating wavelength, and is further configured to not substantially reflect other wavelengths outside of the target operating wavelength.

In various embodiments, device additionally includes reflector optic 204 which may be configured to fold the collected beam generated by collector optic 202. Accordingly, reflector optic 204 may include a flat mirror that reflects the collected beam, and thus provides directional guidance for the collected beam. In some embodiments, reflector optic 204 is configured to reflect the collected beam in a direction that is substantially orthogonal to a desired wafer plane of a target wafer which often is desired to sit perpendicular to gravity. In this way, reflector optic 204 may orient the collected beam in a direction that is determined based on the preferred orientation of the target wafer, as may be determined based on lithography operations. For example, an orientation of the target wafer may be horizontal and substantially perpendicular to gravity as the target wafer is laid flat for lithography operations. In this example, the collected beam may be substantially parallel to gravity and substantially orthogonal to a target wafer when the wafer is level during a lithography process. Such orientation of the collected beam may allow the wafer plane to be kept horizontal, and thus allow implementation of device 200 where an orientation of a target wafer is given precedence, and components of device 200 are configured to accommodate such design parameters and preferences.

It will be appreciated that the orientation and position of reflector optic 204 may be determined based on the orientation and position of the target wafer and intermediate components, such as collimator optic 206 and grating 212 discussed in greater detail below such that reflector optic 204 is configured to guide the collected beam to the target wafer and intermediate components regardless of their orientation relative to some reference direction, such as gravity. Accordingly, while embodiments disclosed herein described the collected beam as being substantially orthogonal to the target wafer plane, such orientation may be sufficiently orthogonal to provide sufficient light to achieve the designated photo flux used for lithography operations. Accordingly, reflector optic 204 may be positioned at any angle suitable to provide sufficient light from collector optic 202 to downstream components such as collimator optic 206, grating 212, and a target wafer.

In various embodiments, device 200 additionally includes collimator optic 206 which is configured to receive the reflected collected beam from reflector optic 204, and is further configured to generate a collimated output based on the received light. In various embodiments, the collimated output may be a substantially collimated output that is sufficiently collimated to provide a designated photon flux that is sufficient for lithography operations. Accordingly, in some embodiments, the collimated output may be at least partially collimated. Moreover, collimator optic 206 is further configured to maintain the direction and angle imparted by reflector optic 204. In various embodiments, collimator optic 206 is configured to include various collimating optical elements that are configured to collimate the received collected beam, which may still include incoherent light. For example, collimator optic 206 may include first collimator element 208 that includes a collimator mirror. In various embodiments, first collimator element 208 is placed approximately one focal length away from the intermediate focus of collector optic 202, where the one focal length is the focal length of first collimator element 208. Moreover, collimator optic 206 may also include second collimator element 210 that is configured to approximately image the pupil of the first collimator element 208 to a center of a downstream component, such as grating 212. In some embodiments, first collimator element 208 and second collimator element 210 are spherical and are configured to have a spherical geometry of their reflective surfaces.

In various embodiments, first collimator element 208 and second collimator element 210 may be mirrors, or any other suitable reflective device such as reflection or transmission zone plates. Moreover, while FIG. 2 illustrates the use of multiple collimator elements, it will be appreciated that collimator optic 206 may include a single collimator element. For example, collimator optic 206 may include a single collimator element, or may include multiple collimator elements. Moreover, such collimator elements may be reflective elements such as reflective zone plates, or may be transmissive elements such as transmission zone plates.

As shown in FIG. 2, the output of collimator optic 206 may be provided to an optical grating, such as grating 212. As similarly discussed above, grating 212 may include multiple gratings configured to generate an interference pattern used for lithography operations on a target wafer. Accordingly, grating 212 may be a dual grating configured to use collimated light to generate such an interference pattern. Thus, magnification provided by collector optic 202 and collimation provided by collimator optic 206 provide both light concentration and collimation that enable the use of grating 212 even when a relatively low-cost incoherent light source is initially used for illumination.

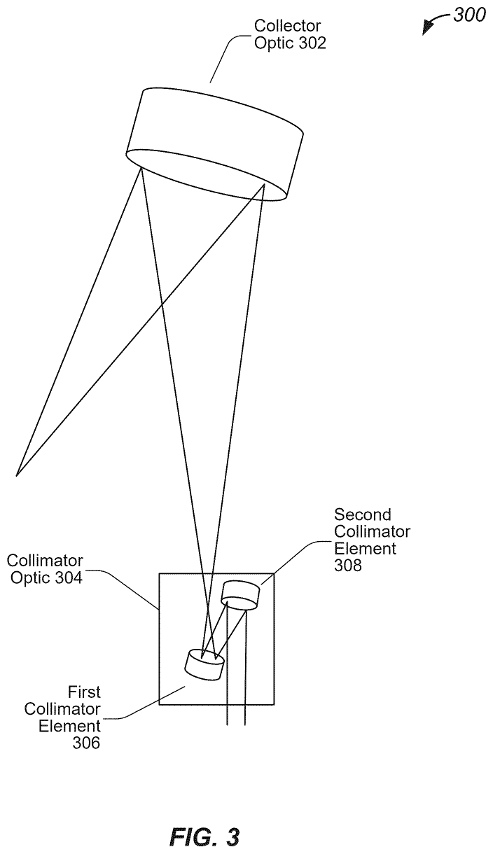

FIG. 3 illustrates another example of a device for lithography illumination, configured in accordance with some embodiments. As similarly discussed above, embodiments disclosed herein enable the highly efficient collection of light from an incoherent light source while maintaining divergence parameters suitable for interference lithography applications. Accordingly, a device, such as device 300, may include optical elements configured to provide a large angle of light collection and collimation to enable such efficient generation of coherent light for interference lithography.

As shown in FIG. 3, device 300 may be implemented without a reflector optic. Accordingly, device 300 may include collector optic 302 which, as similarly discussed above, is configured to receive incoherent light from a light source. As shown in FIG. 3, collector optic 302 is configured to include a collector mirror that is positioned to generate a collected beam that is substantially orthogonal to a target wafer plane. In this way, the positioning of the light source and collector optic 302 may be configured such that the collected beam generated by collector optic 302 as an angle and direction suitable for lithography operations performed on the target wafer.

As also discussed above, device 300 includes collimator optic 304 which may be configured to collimate a collected beam generated by collector optic 302. For example, collimator optic may be configured to include first collimator element 306 and second collimator optic 308 that may be configured to receive incoherent light from collector optic 302, and generate a collimated output that is provided to a downstream component, such as a grating, for lithography operations. Accordingly, positioning of collector optic 302 and collimator optic 304 relative to a light source may be configured such that no additional optics are needed to generate a light output suitable for interference lithography operations.

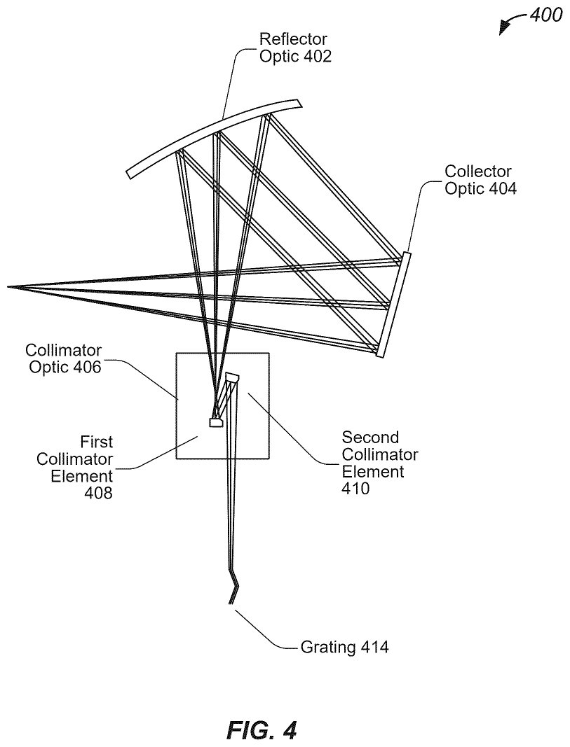

FIG. 4 illustrates an additional example of a device for lithography illumination, configured in accordance with some embodiments. As similarly discussed above, embodiments disclosed herein enable the highly efficient collection of light from an incoherent light source while maintaining divergence parameters suitable for interference lithography applications.

Accordingly, as similarly discussed above, a device, such as device 400, may include collector optic 404 that is configured to receive incoherent light from a light source. Moreover, device 400 may further include collimator optic 406 which may be configured to collimate a collected beam generated by collector optic 404. For example, collimator optic may be configured to include first collimator element 408 and second collimator optic 410 that may be configured to receive the collected beam of incoherent light generated by collector optic 404, and may be further configured to generate a collimated output that is provided to a downstream component, such as a grating, for lithography operations.

As shown in FIG. 4, device 400 additionally includes reflector optic 402 which, as similarly discussed above with reference to FIG. 2, is configured to provide angular guidance for light generated by the incoherent light source. In device 400, the position of reflector optic 402 and collector optic 404 may be configured such that reflector optic 402 is configured to receive the output of the light source, and provides the reflected output to collector optic 404. In some embodiments, such a configuration of reflector optic 402 and collector optic 404 may provide additional protection for collector optic 404 as it is not directly exposed to the light source, and thus may be protected from source debris and other emissions from the light source that might otherwise be harmful to collector optic 404.

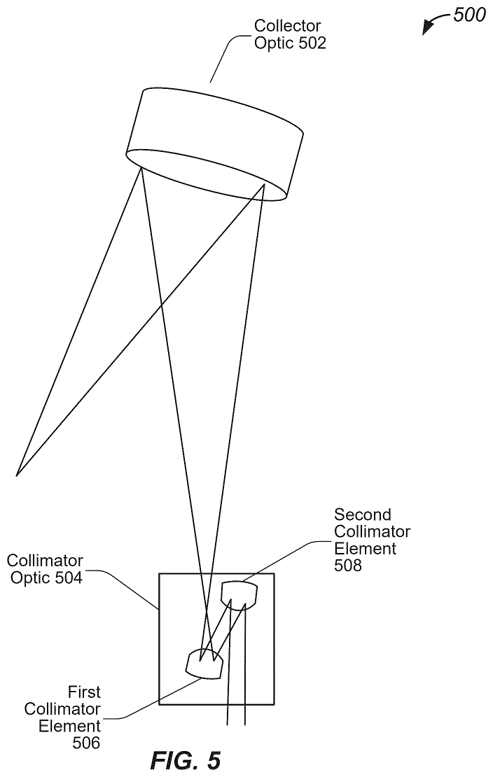

FIG. 5 illustrates another example of a device for lithography illumination, configured in accordance with some embodiments. As similarly discussed above, a device, such as device 300, may include optical elements configured to provide a large angle of light collection and collimation to enable efficient generation of coherent light for interference lithography. As will be discussed in greater detail below, elements included in a collimator optic may be configured to have an aspherical geometry in their reflective surfaces.

In various embodiments, device 500 may include collector optic 502 that provides a collected beam to collimator optic 504. As similarly discussed above, collimator optic 504 may be configured to include first collimator element 506 and second collimator element 508 that generate a collimated output provided to downstream components, such as a grating, for lithography operations. In various embodiments, both first collimator element 506 and second collimator element 508 are aspherical elements. Thus, both first collimator element 506 and second collimator element 508 may have reflective surfaces, such as mirrors, that have an aspherical geometry. It will be appreciated that the curvature shown in FIG. 5 is not to scale and has been enhanced for illustrative purposes. When configured in this way, the angles of incidence on the collimator elements may be increased, thus increasing and improving the clearance between the illuminating beam received from a light source and the physical edges of the collimator elements and their respective mounting wall while maintaining collimating capabilities of collimator optic 504. In this way, an aspherical configuration of first collimator element 506 and second collimator element 508 may allow for larger incidence angles without experiencing deterioration in collimation from factors such as geometric aberrations.

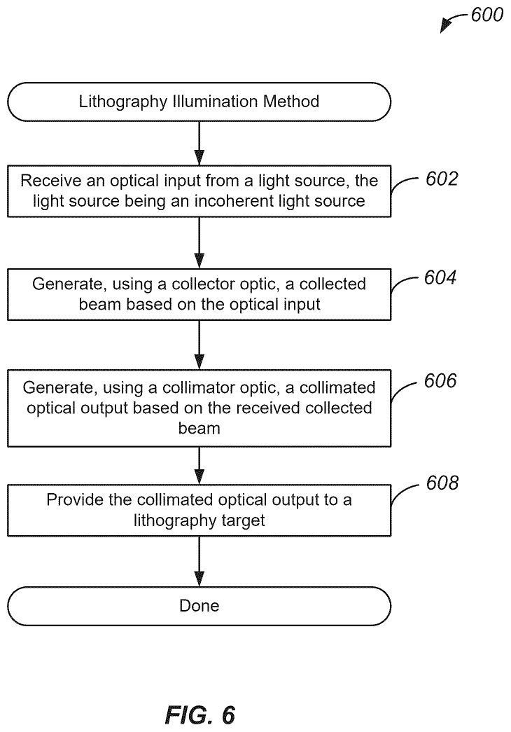

FIG. 6 illustrates an example of a method for lithography illumination, performed in accordance with some embodiments. As similarly discussed above, embodiments disclosed herein provide highly efficient collection of light from an incoherent light source while maintaining divergence parameters suitable for interference lithography applications. Accordingly, a method, such as method 600, may be performed to collect and collimate light from an incoherent light source, and generate an output capable of being used in interference lithography applications.

Method 600 may perform operation 602 during which an optical input may be received from a light source. As similarly discussed above, the light source may be an EUV light source that generates EUV light. Such EUV light may be incoherent light that is not collimated. Accordingly, such light may be received at a component of an optical device that is configured to generate light used during lithography operations.

Method 600 may perform operation 604 during which a collected beam may be generated based on the received optical input. Thus, according to various embodiments, a component of the optical device, such as a collector optic, may be used to collect a designated angular range of light generated by the light source. Such an angular range may be determined based, at least in part, on the amount of partial coherence that is desired for the interference lithography module which may also determine the effective depth of focus of the interference lithography module. The distance between the collector optic focus and a collector mirror may be determined, at least in part, on an amount of light concentration desired to ensure that the collimated output ultimately generated has a sufficient intensity for lithography operations.

Method 600 may perform operation 606 during which a collimated optical output may be generated based on the received collected beam. According to various embodiments, a collimator optic may receive the collected beam, and may use a configuration of collimator elements to generate an output that includes collimated light. In this way, the collected beam that includes incoherent light may be collimated to generate an output that is suitable for use in the interference lithography module.

Method 600 may perform operation 608 during which the collimated optical output may be provided to a lithography target. As similarly discussed above, the collimated optical output may be provided to one or more optical gratings. More specifically, the collimated optical output may be provided to the lithography illumination module that is used for lithography operations. In one example, multiple gratings may be used to generate an interference pattern, and the resulting interference pattern may be provided to a lithography target. Such a lithography target may be a target silicon wafer that is undergoing lithography operations.

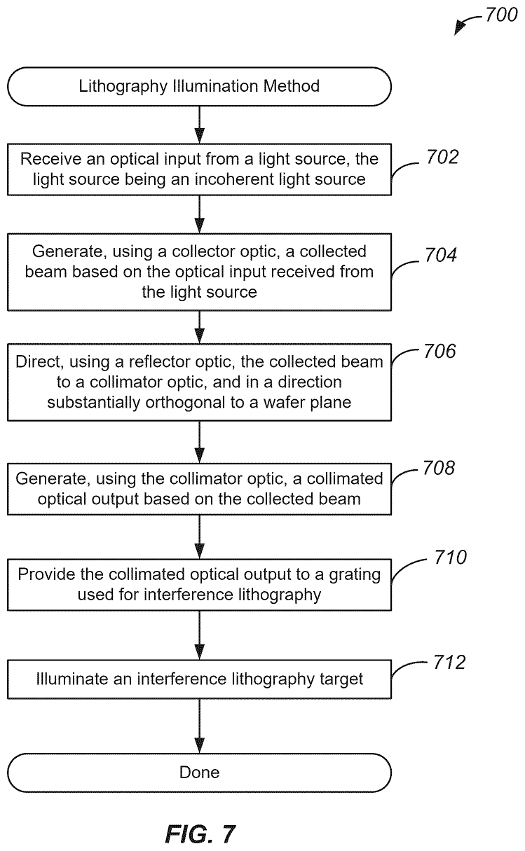

FIG. 7 illustrates another example of a method lithography illumination, performed in accordance with some embodiments. As similarly discussed above, embodiments disclosed herein generate partially coherent, nominally collimated light for interference lithography applications. Accordingly, a method, such as method 700, may be performed to collect and collimate light from an incoherent light source, and generate an output capable of being used in interference lithography applications.

Method 700 may perform operation 702 during which an optical input may be received from a light source. As similarly discussed above, the light source may be an EUV light source that generates EUV light. Such EUV light may be incoherent light that is not collimated. As also discussed above, the light may be received at a component of an optical device. For example, the light may be received at a collector optic that includes a collector mirror. In some embodiments, a reflector optic that includes a reflector mirror may be positioned between the collector optic and the light source, and may first provide directional guidance for the received light.

Method 700 may perform operation 704 during which a collected beam may be generated based on the optical input received from the light source. Accordingly, the collector optic may receive the optical input, and may generate a collected beam based on the received input as well as optical parameters of a component of the collector optic, such as a collector mirror. Accordingly, the collector mirror may have a size and curvature configured to collect a designated angular range of light generated by the light source, and may also have a curvature configured to apply an amount of convergence to focus the collected beam at a designated focal length. As similarly discussed above, the designated angular range may be determined based, at least in part, on an amount of partial coherence desired in the collected light as may be determined based on constraints and requirements of the subsequent lithography operations.

Method 700 may perform operation 706 during which the collected beam may be directed by a reflector optic to a collimator optic and in a direction substantially orthogonal to a wafer plane. Accordingly, as similarly discussed above, the reflector optic may include a flat mirror that is configured to modify an angle and trajectory of the collected beam. In one example, the direction of the output generated by the reflector optic may be substantially parallel to gravity, and may be substantially orthogonal to a wafer plane of a target wafer. As discussed above, while some embodiments disclose a substantially orthogonal direction, it will be appreciated that the collected beam may be directed to the collimator optic in any suitable direction that provides sufficient light and photo flux to the collimator optic and target wafer. It will also be appreciated that while the reflector optic is described as being positioned between the collector optic and the collimator optic, as similarly discussed above, the reflector optic may instead be positioned between the light source and the collector optic.

Method 700 may perform operation 708 during which a collimated optical output may be generated based on the collected beam. Accordingly, the collimator optic may receive the collected beam from the reflector optic, and may use a configuration of collimator elements to generate an output that includes collimated light. In this way, the collected beam that includes incoherent light may be collimated to generate an output that is suitable for use in the interference lithography module. Moreover, the collimator optic may maintain the direction and angle imparted by the reflector optic. In this way, an output of the collimator optic may also be substantially parallel to gravity, and may be substantially orthogonal to a wafer plane of a target wafer.

Method 700 may perform operation 710 during which the collimated optical output may be provided to a grating. As similarly discussed above, the collimated optical output may be provided to one or more optical gratings. For example, the grating may include an arrangement of multiple gratings of differing pitch. For example, the grating may include a first grating configured to generate a diffracted output based on the collimated light received from the collimator optic. The grating may also include a second grating configured to generate an interference pattern based on a recombination of the diffracted orders. Such an interference pattern may be provided as an output of the grating and used for lithography operations.

Method 700 may perform operation 712 during which a lithography target may be illuminated. Accordingly, the resulting interference pattern may be provided to a lithography target during subsequent lithography operations. In one example, the lithography target is a target silicon wafer that is undergoing lithography operations. Accordingly, the target silicon wafer may be illuminated to implement such lithography operations, and magnification, collimation, and directionality provided by the collector optic, the reflector optic, and the collimator optic may ensure that such lithography operations are possible.

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present embodiments are to be considered illustrative and not restrictive.

What is claimed is:

1. A system comprising:
a light source configured to generate a first optical output; and
an optical device configured to receive the first optical output, the optical device comprising:
a collector optic configured to receive the first optical output from the light source, and further configured to generate a second optical output based, at least in part, on the first optical output, the second optical output comprising a collected beam of light produced by the light source; and
a collimator optic configured to receive the second optical output from the collector optic, and further configured to generate a third optical output that includes substantially collimated light.

2. The system of claim 1 further comprising a reflector optic positioned between the collector optic and the collimator optic.

3. The system of claim 1 further comprising a reflector optic positioned between the light source and the collector optic.

4. The system of claim 1, wherein the collimator optic comprises a plurality of aspherical mirrors configured to receive a noncollimated optical input, and further configured to generate a substantially collimated optical output based on the received noncollimated optical input.

5. The system of claim 1, wherein an orientation of the second optical output of the collector optic is substantially orthogonal to a lithography target.

6. The system of claim 1, wherein the collimator optic comprises at least one of a reflection zone plate and a transmission zone plate.

7. The system of claim 6 further comprising:
an optical grating configured to receive the third optical output, and further configured to generate a fourth optical output provided to a lithography target.

8. The system of claim 1, wherein the optical grating comprises a multiple-grating interferometer.

9. The system of claim 1, wherein the light source is an extreme ultraviolet (EUV) light source configured to generate EUV light.

10. A device comprising:
a collector optic configured to receive a first optical output from a light source, and further configured to generate a second optical output based, at least in part, on the first optical output, the second optical output comprising a collected beam of light produced by the light source; and
a collimator optic configured to receive the second optical output from the collector optic, and further configured to generate a third optical output that includes substantially collimated light, the third optical output being capable of being provided to a lithography target.

11. The device of claim 10 further comprising a reflector optic positioned between the collector optic and the collimator optic.

12. The device of claim 10 further comprising a reflector optic positioned between the light source and the collector optic.

13. The device of claim 10, wherein the collimator comprises a plurality of aspherical mirrors configured to receive a noncollimated optical input, and further configured to generate a substantially collimated optical output based on the received noncollimated optical input.

14. The device of claim 10, wherein an orientation of the second optical output of the collector optic is substantially orthogonal to the lithography target.

15. The device of claim 10 further comprising:
an optical grating configured to receive the third optical output, and further configured to generate a fourth optical output provided to the lithography target, wherein the optical grating comprises a multiple-grating interferometer.

16. A method comprising:
receiving a first optical output from a light source;
generating, using collector optic, a second optical output based on the first optical output, the second optical output comprising a collected beam of light produced by the light source;
providing the second optical output to collimator optic; and
generating, using the collimator optic, a third optical output comprising collimated light, the third optical output being capable of being provided to a lithography target.

17. The method of claim 16, wherein a reflector optic is positioned between the collector optic and the collimator optic and provides the second optical output from the collector optic to the collimator optic.

18. The method of claim 16, wherein a reflector optic is positioned between the light source and the collector optic and provides the first optical output from the light source to the collector optic.

19. The method of claim 16, wherein the collimator comprises a plurality of aspherical mirrors that receive a noncollimated optical input, and generate a collimated optical output based on the received noncollimated optical input.

20. The method of claim 16, wherein an optical grating receives the third optical output, and further generates a fourth optical output provided to the lithography target, wherein the optical grating comprises a multiple-grating interferometer.
